(19) United States
(12) Patent Application Publication
(10) Pub. No.: US 2008/0157215 A1
(43) Pub. Date: Jul. 3, 2008

(54) Inter-Diffusion Barrier Structures for Dopants in Gate Electrodes, and Method for Manufacturing

(75) Inventor: Katsura Miyashita, Kanagawa (JP)

Correspondence Address: BANNER & WITCOFF, LTD., 1100 13th STREET, N.W., SUITE 1200, WASHINGTON, DC, 20005-4051, US

(73) Assignee: TOSHIBA AMERICA ELECTRONIC COMPONENTS, INC., Irvine, CA (US)

(21) Appl. No.: 11/617,001

(22) Filed: Dec. 28, 2006

(51) Int. Cl. H01L 27/092; H01L 21/8238

(52) U.S. Cl. 257/374; 438/230; 257/E27.092; 257/E21.632

(57) ABSTRACT

Structures for reducing or even preventing the diffusion from an NFET side of a gate to a PFET side of the gate in a semiconductor device are disclosed, as well as manufacturing methods thereof. A diffusion barrier is formed in the shared gate at the N/P boundary between the NFET and the PFET. The diffusion barrier is doped with one or more types of ions, such as, but not limited to, oxygen, nitrogen, fluorine, silicon, germanium, or xenon ions. By using a diffusion barrier as disclosed herein, the diffusion of ions through a common gate from the NFET side to the PFET side in a CMOS technology semiconductor device node may be significantly reduced or even prevented altogether. This may further result in relatively higher performance of the NFET/PFET pair.

### BACKGROUND

In semiconductor devices using complementary metal-oxide semiconductor (CMOS) technology, transistor polysilicon gates are pre-doped to improve dopant activation in the gates and to enable the use of an ultra-thin gate dielectric layer. In 90 nm and 65 nm CMOS technology nodes, an N type field-effect transistor (NFET) and a P type FET (PFETs) are paired together to share a common gate. At these scales, the portion of the polysilicon gate devoted to the NFET typically receive N type doping (such as with phosphorus or arsenic ions). On the other hand, the portion of the polysilicon gate devoted to the PFET does not typically receive any pre-doping to avoid boron penetration into the ultra-thin gate dielectric. When pre-doping an NFET polysilicon gate, the implant dose is typically extremely high, such as 1e15 cm⁻² or higher. This implant dose is usually higher than the source/drain implant doses, however this has been acceptable since it has been believed that high dosage pre-doping of NFET gates in these technologies do not degrade FET characteristics.

In modern advanced CMOS technologies using increasingly smaller scales, NFET/PFET pairs are positioned closer to each other than ever before. For instance, referring to FIG. 1, a PFET is formed with a silicon N well 101, a P type drain 103, a P type source 104, and a P type polysilicon gate 107, and an NFET is formed with a silicon P well 102, an N type drain 105, an N type source 106, and an N type polysilicon gate 108. Polysilicon gate 107 and polysilicon gate 108 are the same physical gate structure but have different types of doping. As can be seen in FIG. 2, the pre-doped dopant of polysilicon gate 108 tend to diffuse from the NFET side to the PFET side into polysilicon gate 107. This effect is most strongly seen during manufacturing where thermal processes are used such as in annealing and oxidation steps. Although this diffusion has always occurred in larger scale CMOS technologies, it becomes more important with smaller scales and can have a substantially detrimental effect on FET characteristics. As the distance between the NFET and the PFET decreases, such diffusion becomes even more problematic. In addition, misalignment during lithography steps becomes more important with smaller scales, potentially making the diffusion problem even worse.

As the distance from the NFET/PFET boundary 109 located at the boundary between N well 101 and P well 102 (also referred to herein as the N/P boundary) to the edge of the active area 103, 104 of the PFET decreases, especially below 100 nm, the threshold voltage of the PFET increases and the drive current of the PFET decreases. This is highly undesirable and is caused in large part by the above-discussed diffusion problem.

### SUMMARY

A way to reduce or even prevent the above-discussed diffusion problem is needed. Accordingly, aspects of the present disclosure discuss ways for accomplishing this. For instance, a diffusion barrier may be formed in the gate at the N/P boundary. The diffusion barrier may be doped with one or more types of ions, such as, but not limited to, oxygen, nitrogen, fluorine, silicon, germanium, or xenon ions.

In addition to disclosing illustrative structures that include such a diffusion barrier, methods for manufacturing such structures are disclosed.

By using a diffusion barrier as disclosed herein, the diffusion of ions through a common gate from the NFET side to the PFET side in a CMOS technology semiconductor device node may be significantly reduced or even prevented altogether. This may further result in relatively higher performance of the NFET/PFET pair.

These and other aspects of the disclosure will be apparent upon consideration of the following detailed description of illustrative embodiments.

### BRIEF DESCRIPTION OF THE DRAWINGS

A more complete understanding of the present invention and the advantages thereof may be acquired by referring to the following description in consideration of the accompanying drawings, in which like reference numbers indicate like features, and wherein:

FIG. 1 is a plan view of a conventional NFET/PFET pair of a semiconductor device.

FIG. 2 is a plan view illustrating the diffusion problem in the NFET/PFET pair of FIG. 1.

FIG. 3 is a plan view of an illustrative NFET/PFET pair of a semiconductor device including an illustrative diffusion barrier.

FIG. 4 is a magnified view of a portion of FIG. 3.

FIGS. 5, 7, 9, 11, 12, 14, and 16 are plan views showing the NFET/PFET pair of FIG. 3 during various illustrative manufacturing steps.

FIG. 6 is a side cut-away view corresponding to the plan view of FIG. 7.

FIG. 8 is a side cut-away view corresponding to the plan view of FIG. 9.

FIG. 10 is a side cut-away view corresponding to the plan view of FIG. 11.

FIG. 13 is a side cut-away view corresponding to the plan view of FIG. 14.

FIG. 15 is a side cut-away view corresponding to the plan view of FIG. 16.

FIG. 17 shows an approximate trend of PFET threshold voltage depending upon the distance between the N/P boundary and a PFET, and how it may be improved by the addition of a diffusion barrier.

FIG. 18 shows an approximate trend of PFET drive current depending upon the distance between the N/P boundary and a PFET, and how it may be improved by the addition of a diffusion barrier.

FIGS. 19-22 are plan views of an NFET/PFET pair including a diffusion barrier offset in various illustrative ways relative to the N/P boundary.

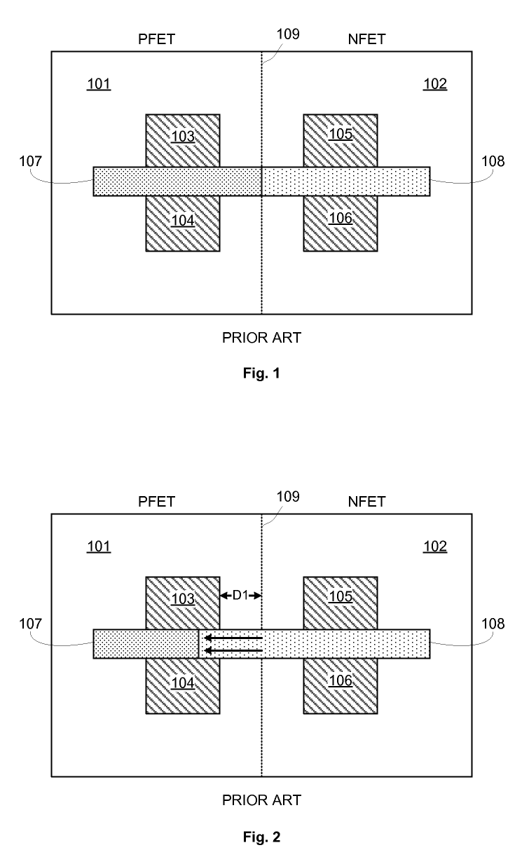

### DETAILED DESCRIPTION OF ILLUSTRATIVE EMBODIMENTS

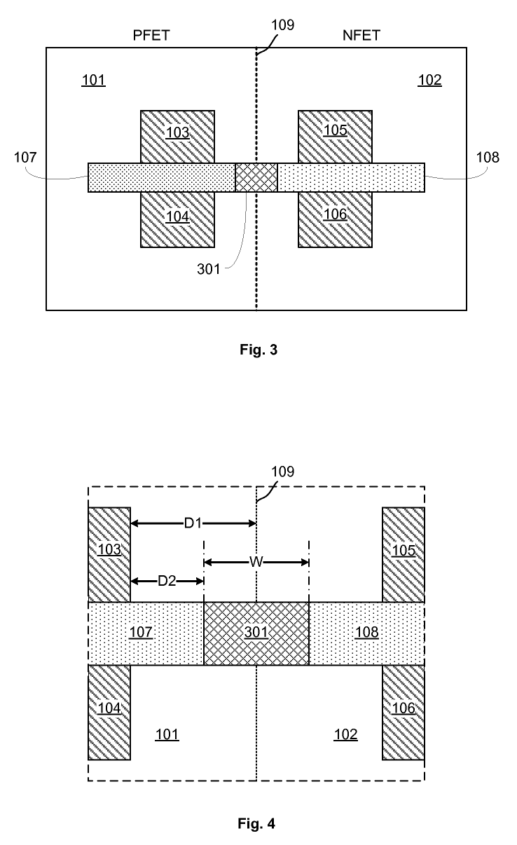

Referring to FIGS. 3 and 4, a diffusion barrier 301 may be formed in gate 107/108 at N/P boundary 109. Diffusion barrier 301 may be formed by an amorphization implant of ions such as, but not limited to, oxygen, nitrogen, fluorine, silicon, germanium, carbon, and/or xenon ions. Diffusion barrier 301 may reduce, or even completely prevent, diffusion of ions from gate portion 108 into gate portion 107.

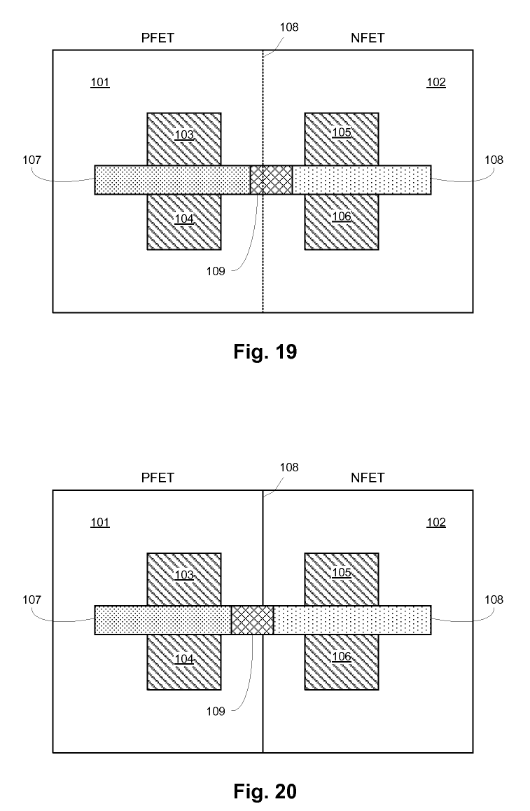

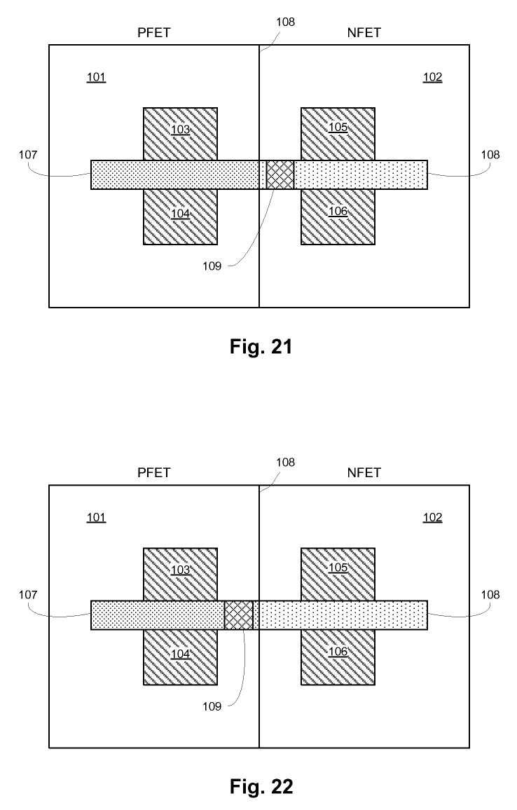

In this particular embodiment, diffusion barrier 301 is positioned so as to be approximately centered about N/P boundary 109 and extends in opposing directions from N/P boundary 109 by approximately the same distance 0.5*W. Thus, diffusion barrier 301 has a width W along the lengthwise axis of gate 107/108. However, diffusion barrier 301 may be partially or fully offset from N/P boundary 109. Such an offset may be intentionally designed or may be a result of misalignment of lithography. For instance, diffusion barrier 301 may be positioned as shown in any of FIGS. 19-22.

However, for even better performance, it is desirable that diffusion barrier 301 be positioned such that it is sufficiently spaced from the active areas 103/104 and 105/106 of the PFET and the NFET (see distance D2) while at the same time width W is sufficiently large to have the desired diffusion reducing effect. For instance, in one illustrative embodiment, W is approximately 120 nm, D1 is approximately 100 nm, and D2 is approximately 40 nm. It may also be desirable for better performance that diffusion barrier 301 does not overlap either of active areas 103/104 and 105/106.

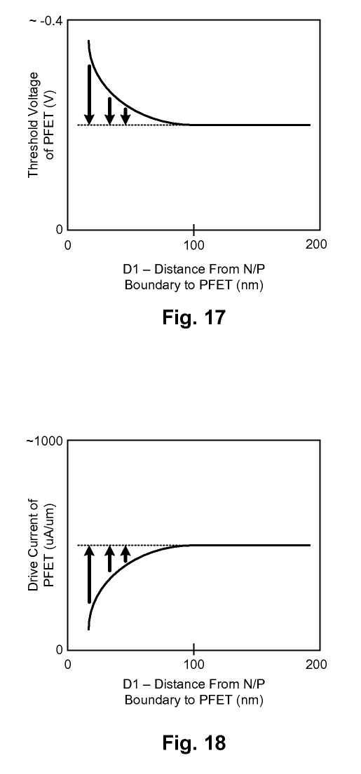

Referring to FIGS. 17 and 18, compared with conventional structures, an illustrative effect of the diffusion barrier on the PFET threshold voltage and the PFET drive current are shown. Normally, with decreasing distance D1, the threshold voltage increases and the drive current decreases, both of which is highly undesirable. However, when using a diffusion barrier as described herein, the threshold voltage may not increase as much, and the drive current may not decrease as much, with decreasing distance D1 (the effect of the diffusion barrier being indicated in FIGS. 17 and 18 by arrows).

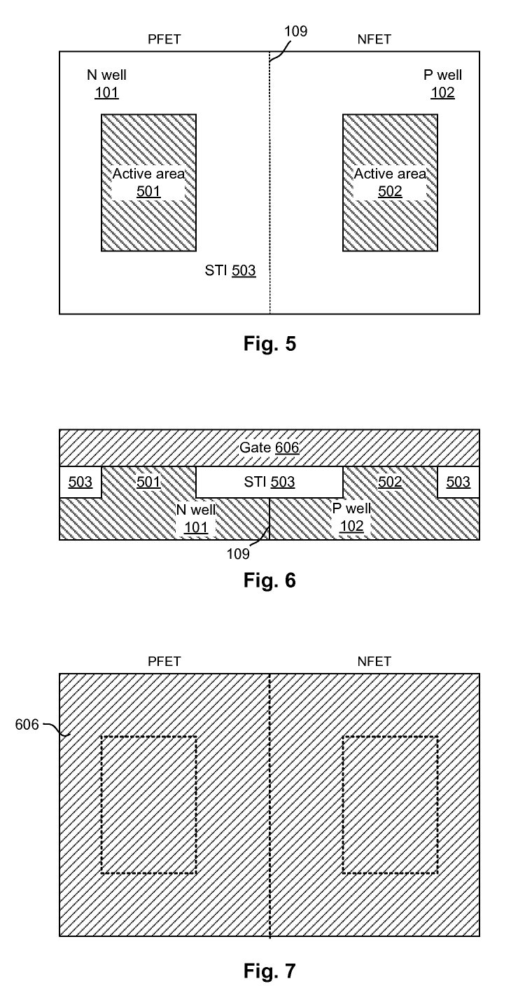

An illustrative method for manufacturing a semiconductor device having an NFET/PFET pair with a diffusion barrier in the shared gate is now described with reference to FIGS. 5-16. Referring to FIG. 5, a semiconductor device is formed in a conventional manner having, among other features, N well 101 and P well 102. Within N well 101 is formed or reserved an active area 501 for a PFET, and within P well 102 is formed or reserved an active area 502 for an NFET. In addition, a shallow trench isolation (STI) layer 503 is embedded in N well 101 and P well 102 in a conventional manner, to isolate active areas 501 and 502.

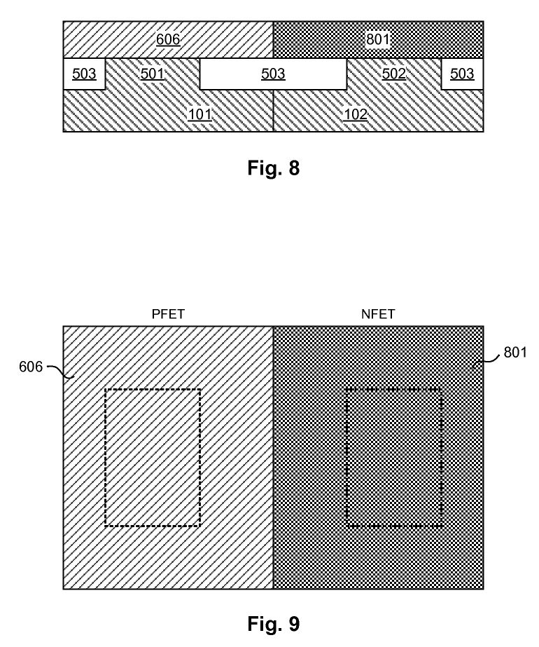

Next, referring to FIGS. 6 and 7, a polysilicon layer 606 is formed in a conventional manner over the semiconductor device, covering N well 101, P well 102, STI layer 503, and active areas 501, 502. Instead of polysilicon, layer 606 may be another conductive material or combination of materials such as a crystalline material or a metal.

Next, referring to FIGS. 8 and 9, the NFET side (i.e., P well 102) receives N type pre-doping, such as a phosphorus or arsenic implant, resulting in N doped polysilicon layer 801.

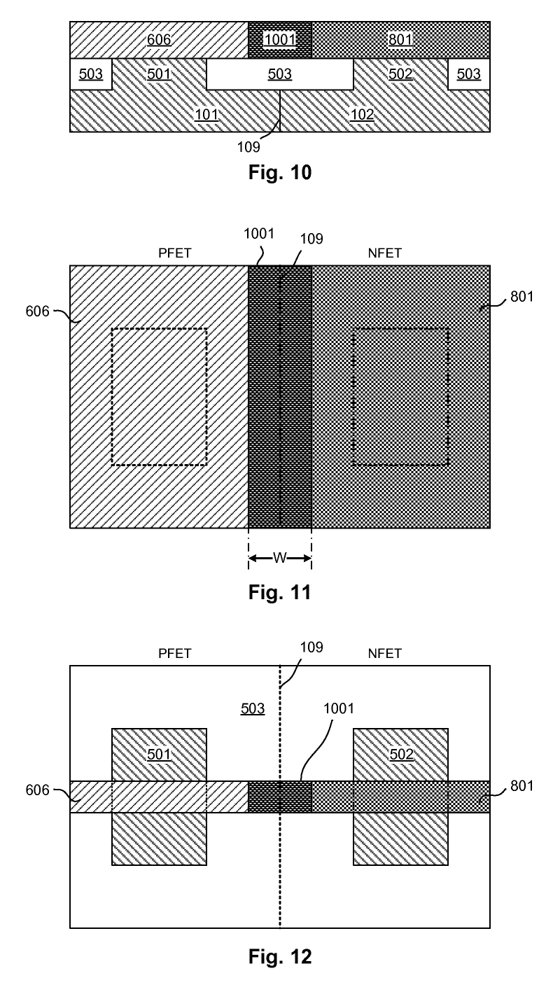

Next, referring to FIGS. 10 and 11, an amorphization implant is performed at an elongated region 1001 that includes N/P boundary 109 and extends a distance W/2 in each of the two opposing directions that are perpendicular to N/P boundary 109, for a total width W. To perform such an implant, ions such as, but not limited to, oxygen, nitrogen, fluorine, silicon, germanium, carbon, and/or xenon ions, are implanted into region 1001. The ions may be N+ ions or N− ions. The implant may be at a dosage, for example in the range of 5e13 cm⁻² to 1e15 cm⁻² or 1e13 cm⁻² to 5e15 cm⁻². This region 1001 will eventually become the diffusion barrier having width W.

Next, referring to FIG. 12, lithography and etching processes are used to remove one or more portions of polysilicon layer 606, region 1001, and doped polysilicon layer 801, to leave an elongated gate electrode structure formed by those remaining layers and that extends lengthwise in a direction perpendicular to N/P boundary 109.

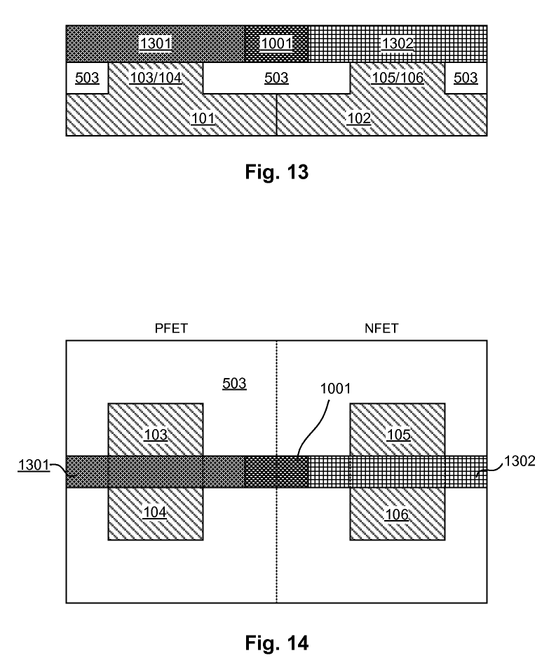

Next, referring to FIGS. 13 and 14, re-oxidation is performed, the NFET receives N type implants, and the PFET receives P type implants, for source/drain/gate formation. This results in P doped polysilicon layer 1301, N doped polysilicon layer 1302, P doped source/drain regions 103/104, and N doped source/drain regions 105/106. In this embodiment, re-oxidation is performed after layer 1001 is formed, which acts as a diffusion barrier.

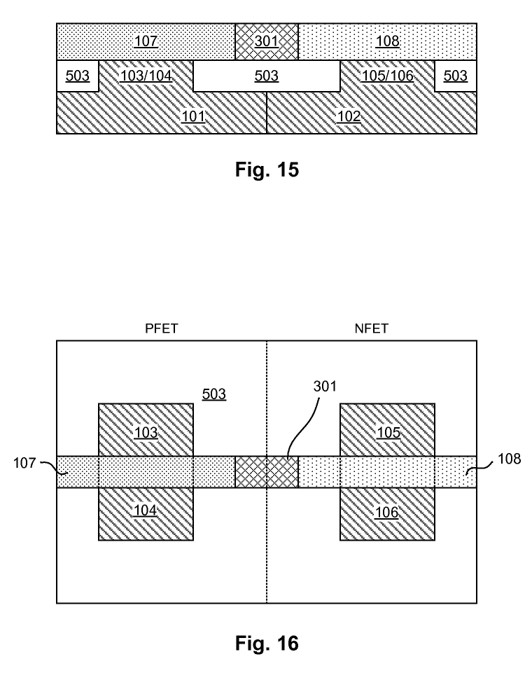

Next, referring to FIGS. 15 and 16, activation anneal is performed, such as rapid thermal anneal (RTA), spike RTA, flash anneal, and/or laser anneal. This activates the implanted dopants, resulting in activated PFET gate portion 107, layer 301 (which continues to act as a diffusion barrier), and NFET gate portion 108. During this annealing, diffusion barrier 301 prevents or otherwise reduces diffusion of ions from the NFET side to the PFET side of the gate structure.

Thus, structures for reducing or even preventing the diffusion from an NFET side of a gate to a PFET side of the gate has been disclosed, as well as manufacturing methods thereof.

What is claimed is:

1. A semiconductor device, comprising:
a silicon layer; and
an N type transistor and a P type transistor sharing a common gate, wherein the gate is disposed on a silicon layer and includes a diffusion barrier disposed between the N type transistor and the P type transistor.

2. The semiconductor device of claim 1, wherein the diffusion barrier has an ion concentration greater than a portion of the gate disposed over each of the N type transistor and the P type transistor.

3. The semiconductor device of claim 1, wherein a portion of the gate over each of the N type transistor and the P type transistor is non-amorphized polysilicon, and the diffusion barrier is amorphized polysilicon.

4. The semiconductor device of claim 1, wherein a portion of the gate over the N type transistor is P type doped polysilicon and a portion of the gate over the P type transistor is N type doped polysilicon.

5. The semiconductor device of claim 1, wherein a portion of the gate over each of the N type transistor and the P type transistor is a crystalline material, and the diffusion barrier is an amorphized material.

6. The semiconductor device of claim 1, wherein the gate is a doped metal.

7. The semiconductor device of claim 1, further including a region of insulating material embedded in the silicon layer between the N type transistor and the P type transistor, wherein the diffusion barrier is disposed over the insulating material.

8. The semiconductor device of claim 7, wherein the diffusion barrier is disposed completely over the insulating material.

9. The semiconductor device of claim 1, wherein the diffusion region is approximately 120 nm in length in a lengthwise direction of the gate.

10. The semiconductor device of claim 1, wherein the N type transistor has a first active region and the P type transistor has a second active region, and wherein the diffusion region does not extend into either the first or second active regions.

11. A semiconductor device, comprising:
a silicon layer having an N type doped silicon region and a P type doped silicon region; and
a continuous polysilicon layer disposed on the silicon layer and disposed over both the N type and P type doped silicon regions, wherein the polysilicon layer has an amorphized polysilicon region disposed between the N type and P type doped silicon regions, a first non-amorphized polysilicon region disposed over the N type doped silicon region, and a second non-amorphized polysilicon region disposed over the P type doped silicon region.

12. The semiconductor device of claim 11, wherein the amorphized polysilicon region does not extend over either of the N type and P type doped silicon regions.

13. The semiconductor device of claim 11, further including an insulating region embedded in the silicon layer of a material different from the N type and P type doped silicon regions and extending between the N type and P type doped silicon regions, wherein the amorphized polysilicon region is disposed completely over the insulating region.

14. The semiconductor device of claim 11, wherein the silicon layer includes an N well containing the P type doped silicon region and a P well containing the N type doped silicon region.

15. A method for manufacturing a semiconductor device, comprising:
providing a silicon layer having an N well and a P well adjacent to the N well at a boundary;
forming a polysilicon layer on the silicon layer including over the N well and the P well;
implanting ions into the polysilicon layer at the boundary, such that the portion of the polysilicon layer at the boundary becomes amorphized while portions of the polysilicon layer on opposing sides of the boundary remain non-amorphized; and
removing a portion of each of the amorphized polysilicon layer and the non-amorphized polysilicon layer.

17. The method of claim 15, further including performing oxidation of the polysilicon layer after the step of removing, wherein the step of implanting is performed before the step of performing oxidation.

18. The method of claim 17, further including forming an oxide layer on the silicon layer, and wherein the step of forming the polysilicon layer includes forming the polysilicon layer on the oxide layer.

19. The method of claim 15, wherein the step of implanting includes implanting the ions with a dosage in the range of 1e13 cm⁻² to 5e15 cm⁻².

20. The method of claim 15, further including annealing the semiconductor device after the step of removing.
